(19) United States
(12) Patent Application Publication
(10) Pub. No.: US 2011/0050055 A1
(43) Pub. Date: Mar. 3, 2011

(54) METHOD FOR MAKING DEVICE HOUSING AND DEVICE HOUSING THEREOF

(75) Inventors: YONG-GANG ZHU, Shenzhen City (CN); DA-WEI DING, Shenzhen City (CN); XIN-WU GUAN, Shenzhen City (CN); CHAO-HSUN LIN, Taipei (TW)

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/755,495

(22) Filed: Apr. 7, 2010

(30) Foreign Application Priority Data
Aug. 28, 2009 (CN) 200910306292.0

(51) Int. Cl. H05K 5/02; C23F 1/00

(52) U.S. Cl. 312/223.1; 216/37

(57) ABSTRACT

A method for making a device housing comprises: providing a metal substrate; etching grooves on a portion of the surface of the metal substrate; forming a metallic coating on the surface of the metal substrate and in the grooves; and removing the metallic coating formed on the surface of the metal substrate not comprising the grooves. A device housing made by the method is also described there.

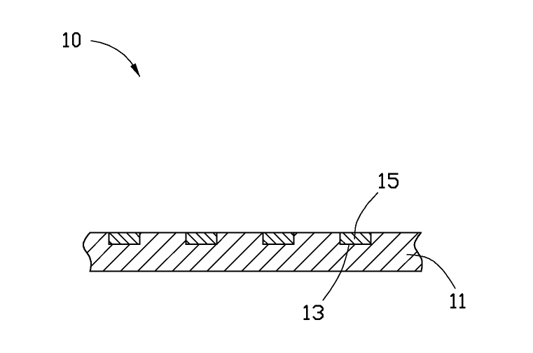

### BACKGROUND

1. Technical Field

The present disclosure relates to a method for making device housing and a device housing made by the method.

2. Description of Related Art

Housings of electronic devices are commonly made of plastic or metal. Metal housings are usually more attractive for their shiny metallic appearance and high strength. However, some may think metal housings have a dull appearance because of a lack of decorative detail. However, if paint or ink coatings are applied to decorate the metal housings, the metallic appearance of the metal housings is reduced.

Therefore, there is room for improvement within the art.

### BRIEF DESCRIPTION OF THE FIGURE

Many aspects of the device housing can be better understood with reference to the following FIGURE. The components in the FIGURE are not necessarily drawn to scale, the emphasis instead being placed upon clearly illustrating the principles of the device housing.

The FIGURE is a cross-sectional view of an exemplary embodiment of a device housing.

### DETAILED DESCRIPTION

A method for manufacturing a device housing may include the following steps: providing a metal substrate; etching grooves on a portion of the surface of the metal substrate; forming a metallic coating on the surface of the metal substrate and in the grooves; removing the metallic coating formed on the surface of the metal substrate not comprising the grooves.

Referring to the FIGURE, a metal substrate 11 is provided. The metal substrate 11 may have the shape of a device housing. The metal substrate 11 may be made of stainless steel, aluminum, aluminum alloy, zinc, zinc alloy, titanium, or titanium alloy.

A plurality of grooves 13 is formed on one surface of the metal substrate 11 by chemical etching. The chemical etching process may be carried out by immersing the metal substrate 11 in an etching solution containing copper ions, iron ions, chlorine ions, sulfate ions, and nitrate ions. During the etching process, chemical reaction occurs at the surface of the metal substrate 11, which etches the metal substrate 11 and forms the grooves 13 in the surface of the metal substrate 11. The surface of the metal substrate 11 where the grooves 13 are not wanted is shielded by a film during the etching process. In this embodiment, each groove 13 may have a depth of about 0.1-0.12 mm. The grooves 13 may form a decorative pattern such as a geometrical pattern.

The surfaces of the grooves 13 are roughened by, for example, blasting the grooves 13 with white corundum (primarily consisting of Al₂O₃) particles having a diameter of about 0.2-0.3 mm under a load of about 1.6 kilograms. The roughening process ensures that subsequent coatings will bond well with the surface of the grooves 13. Surfaces of the metal substrate 11 not needing roughening are shielded by an adhesive tape or a shield workpiece during the roughening process.

The material used for blasting the grooves 13 can also be quartz sand (primarily consisting of SiO₂).

A metallic coating 15 is formed on the surface of the metal substrate 11 and in the grooves 13 by thermal spraying. The metallic coating 15 may have a different color or texture from the metal substrate 11. The metallic coating 15 may be made of aluminum, aluminum alloy, molybdenum, copper, copper alloy, zinc, zinc alloy, or stainless steel. The thickness of the metallic coating 15 may be of about 0.1-0.2 mm.

The metallic coating 15 on the surface of the substrate 11 may then be removed by mechanical polishing, thus only the grooves 13 remain coated with the metallic coating 15 to present an aesthetic appearance of one kind of metal inlaid in another kind of metal. The surface of the metallic coating 15 filled in the grooves 13 may be level with the surface of the metal substrate 11.

Referring to the FIGURE, in an exemplary embodiment, the device housing 10 formed by the method includes a metal substrate 11, a plurality of grooves 13 formed in the metal substrate 11, and a metallic coating 15 formed in the grooves 13. The metal substrate 11 may be made of stainless steel, aluminum, aluminum alloy, zinc, zinc alloy, titanium, or titanium alloy. The grooves 13 may be formed by a chemical etching process. The metallic coating 15 may be formed by thermal spraying. The metallic coating 15 may be of aluminum, aluminum alloy, molybdenum, copper, copper alloy, zinc, zinc alloy, or stainless steel. The surface of the metallic coating 15 may be level with the surface of the metal substrate 11.

The device housing 10 may be, for example, a housing of a mobile phone, a note-book computer, or a digital camera.

It should be understood, however, that even though numerous characteristics and advantages of the present embodiments have been set forth in the foregoing description, together with details of functions of the embodiments, the disclosure is illustrative only, and changes may be made in detail within the principles of the disclosure to the full extent indicated by the broad general meaning of the terms in which the appended claims are expressed.

What is claimed is:

1. A method for making a device housing, comprising:
providing a metal substrate;
etching grooves on a portion of the surface of the metal substrate;
forming a metallic coating on the surface of the metal substrate and in the grooves;
and removing the metallic coating formed on the surface of the metal substrate not comprising the grooves.

2. The method as claimed in claim 1, wherein the metal substrate is made of stainless steel, aluminum, aluminum alloy, zinc, zinc alloy, titanium, or titanium alloy.

3. The method as claimed in claim 1, wherein the step of etching grooves is carried out by immersing the metal substrate in an etching solution.

4. The method as claimed in claim 3, wherein the etching solution contains copper ions, iron ions, chlorine ions, sulfate ions, and nitrate ions.

5. The method as claimed in claim 1, wherein each groove has a depth of about 0.1-0.12 mm.

6. The method as claimed in claim 1, wherein the metallic coating is of aluminum, aluminum alloy, molybdenum, copper, copper alloy, zinc, zinc alloy, or stainless steel.

7. The method as claimed in claim 1, wherein the metallic coating has a thickness of about 0.1-0.2 mm.

8. The method as claimed in claim 1, wherein the step of removing the metallic coating is carried out by mechanical polishing.

9. The method as claimed in claim 1, wherein further including a step of roughening the surfaces of grooves before forming the metallic coating.

10. The method as claimed in claim 9, wherein the roughening process is carried out by blasting the grooves with white corundum or quartz sand.

11. A device housing, including:
a metal substrate, the metal substrate being formed with a plurality of grooves therein; and
a metallic coating formed in the grooves.

12. The device housing as claimed in claim 11, wherein the metal substrate is made of stainless steel, aluminum, aluminum alloy, zinc, zinc alloy, titanium, or titanium alloy.

13. The device housing as claimed in claim 11, wherein each groove has a depth of about 0.1-0.12 mm.

14. The device housing as claimed in claim 11, wherein the metallic coating is of aluminum, aluminum alloy, molybdenum, copper, copper alloy, zinc, zinc alloy, or stainless steel.

15. The device housing as claimed in claim 11, wherein the metallic coating has a thickness of about 0.1-0.2 mm.

16. The device housing as claimed in claim 11, wherein the metallic coating has a surface leveling with the surface of the metal substrate.
